(19) United States
(12) Patent Application Publication
(10) Pub. No.: US 2007/0241456 A1
(43) Pub. Date: Oct. 18, 2007

(54) Conductive structure for electronic device

(75) Inventors: Tze-Hsiang Chao, Hsin Chu City (TW); Chung Ju Wu, Kao Hsiung City (TW)

Correspondence Address: BIRCH STEWART KOLASCH & BIRCH, PO BOX 747, FALLS CHURCH, VA, 22040-0747, US

(73) Assignee: SILICON INTEGRATED SYSTEMS CORP.

(21) Appl. No.: 11/498,146

(22) Filed: Aug. 3, 2006

(30) Foreign Application Priority Data
Apr. 14, 2006 (TW) 095113467

(51) Int. Cl. H01L 23/48

(52) U.S. Cl. 257/734

(57) ABSTRACT

A conductive structure for electronic device includes at least a first conductor, at least a second conductor and a conductive material for connecting the first conductor and the second conductor.

### BACKGROUND OF THE INVENTION

(a) Field of the Invention

The invention relates to a conductive structure, and particularly to a conductive structure for an electronic device.

(b) Description of the Related Art

FIG. 1A shows a cross section of a general integrated circuit (IC) die 10. The integrated circuit die 10 includes a passivation layer PAS, a plurality of metal layers M1˜M6, and a layer core circuit LCO. The passivation layer PAS covers the metal layer M1 to isolate the metal layers M1˜M6 from the conduction of the external circuitry. Each of the metal layers M1˜M6 includes a plurality of metal wires. For example, each metal layer in FIG. 1A includes 6 wires. Any metal wire of the metal layers M1˜M6 can be connected to each other or connected to the layer core circuit LCO according to the design requirements so as to transmit signals. The number of the metal layers is not limited to six layers and is determined by the circuit design requirements of the integrated circuit die 10.

FIG. 1B shows a schematic diagram illustrating the metal layers M1˜M6 along the BB′ line of FIG. 1A. The metal layers M1˜M6, along the BB′ line, forms a mesh-like structure. FIG. 1C shows a schematic diagram illustrating the passivation layer PAS along the AA′ line of FIG. 1A.

Generally after completion of fabricating the integrated circuit die 10, the production process related to assembling the IC die 10 along with other electronic components into one interconnected structure to achieve a specific function is generally termed as “electronic assembly”. In the electronic assembly technique, it's important to consider the “power distribution” while designing the IC die 10. As shown in FIG. 1D, in order to properly supply the external power into the IC die 10, a plurality of input and output pads 11 are formed on the top metal layer (said metal layer M6 in FIG. 1A) to be connected with external supplying power outside the IC die 10 through the passivation openings of the passivation layer PAS. The size of the input and output pads 11a˜11d of the IC die 10 is enlarged in FIG. 1D in order to clearly explain the structure of the input and output pads 11.

Each of the input and output pads 11a˜11d includes a bond pad 111 and an Input and output pad circuit (IO pad circuit) 112. The bond pad 111 is electrically connected with the IO pad circuit 112. The bond pad 111 is used for connecting with the external circuit. The IO pad circuit 112 is an interfacing circuit for the communicating interface between the layer core circuit LCO and the external circuit connected through the bond pad 111. As the IO pad circuit 112 is connected directly to the layer core circuit LCO or through any of the above mentioned metal wires to the layer core circuit LCO, hence each of the input and output pads 11a˜11d functions as the bridge between layer core circuit LCO and the external circuit.

The IC die 10 and the bond pads on the surface of the IC die 10 is shown in proportion in FIG. 2. A plurality of input and output pads 11 as shown in FIG. 1D and a plurality of internal bond pads 13 are formed on the top metal layer (said metal layer M6 in FIG. 1A) through the passivation openings of the passivation layer PAS . According to the IC design, the internal bond pads 13 are connected to the internal circuit of the layer core circuit LCO directly or through one of the above mentioned metal wires. The method for allocating bond pads on the IC die 10 is of multi-concentric pad (MCP) type in which each of the input and output pads 11 is sequentially arranged into one line as in-line pad set. There are many ways to allocate bond pads on the IC die 10. FIG. 2 shows one of the examples. In general, when designing the power distribution for the IC die 10, a bond wire 12 is connected to the bond pad 111 and the external power source VDD or ground source VSS so that the external power source VDD or ground source VSS from the substrate BO is provided for the input and output pad 11. Then the bond wire 12 is also connected to the internal bond pad 13 and another bond pad 111′ of the other input and output pad 11′ wherein the bond pad 111 is connected with the bond pad 111′ by the routing process on the metal layer M1˜M6. Because the internal bond pad 13 is situated at the area nearby the center of the IC die 10, the external power source VDD or ground source VSS can be directly supplied to the center area of the IC die 10 via the bond wire 12, so that the voltage drop (IR drop) from the external power source VDD to the center of the IC die 10 is reduced to achieve the uniform power distribution.

However, the circuits located below the internal bond pad 13 need to be carefully set apart with each other since the applied mechanical force on wire bonding process to attach the bond wire 12 to the internal bond pad 13 is potentially to damage them. Therefore, it is required to improve the method of distributing power by the bond wire 12.

### BRIEF SUMMARY OF THE INVENTION

In light of the above problems, an object of the invention is to provide a conductive structure that replaces the method of using bond wires to connect with the internal bond pad, and to provide excellent power distribution without damaging the die functionality.

According to the invention, the conductive structure for an electronic device comprising at least a first conductor connected to an internal circuitry of the electronic device and provided at a first location of the surface of the electronic device wherein the first location is apart from the center of the surface by a first distance in a first direction; at least a second conductor connected to an internal circuitry of the electronic device and provided at a second location of the surface of the electronic device wherein the second location is apart from the center of the surface by a second distance in a second direction and the second distance is larger than or equal to the first distance; and, a conductive material for connecting the first conductor and the second conductor wherein a portion of the conductive material touches the surface of the electronic device. Of course, the first conductor may be also provided at the center of the surface of the electronic device.

Through the design of the invention, the conductive structure provides the conductive material covering the first and the second conductors by using materials such as silver epoxy or solder paste through dispensing process which is the normal and available production process in IC assembly to cover the path from the first to the second conductors . Thus, the first and second conductors on the surface of the IC die are connected without increasing extra production process. Instead of the prior wire bonding process, the dispensing process is used to connect the first and second conductors on the surface of the IC die. Thus, the dispensing process can reduce the potential damage to the circuit at the center area of the IC die. The excellent power distribution is achieved by the low electrical resistance of the dispensing material through the design of the invention.

### BRIEF DESCRIPTION OF THE DRAWINGS

FIG. 1A shows the cross section of an integrated circuit die.

FIG. 1B shows a schematic diagram illustrating the metal layer by observing along the line BB′ of FIG. 1A.

FIG. 1C shows a schematic diagram illustrating the passivation layer by observing along the line AA′ of FIG. 1A.

FIG. 1D shows the enlarged input and output pads on the top metal layer M6 of an integrated circuit die with a passivation opening on the surface of the passivation layer.

FIG. 2 shows a schematic diagram illustrating an integrated circuit and the allocation of the bond pads on the integrated circuit in proportion.

FIGS. 3A˜3D show schematic diagrams illustrating the allocation of the bond pads on the integrated circuit die and the conductive structure in an embodiment of the invention.

FIGS. 4A˜4C show schematic diagrams illustrating the allocation of the bond pads on the integrated circuit die and the conductive structure in another embodiment of the invention.

FIGS. 5A and 5B show schematic diagrams illustrating the allocation of the bond pads on the integrated circuit die and the conductive structure in another embodiment of the invention.

FIGS. 6A and 6B show schematic diagrams illustrating the allocation of the bond pads on the integrated circuit die and the conductive structure in another embodiment of the invention.

FIG. 7 shows a schematic diagram illustrating the allocation of the bond pads on the integrated circuit die and the conductive structure in another embodiment of the invention.

FIG. 8 shows a schematic diagram illustrating the allocation of the bond pads on the integrated circuit die and the conductive structure in another embodiment of the invention.

FIG. 9 shows a schematic diagram illustrating the allocation of the bond pads on the integrated circuit die and the conductive structure in another embodiment of the invention.

FIG. 10 shows a schematic diagram illustrating the allocation of the bond pads on the integrated circuit die and the conductive structure in another embodiment of the invention.

FIG. 11 shows a schematic diagram illustrating the conductive structure in another embodiment of the invention.

FIG. 12A shows the cross section of the integrated circuit die in another embodiment of the invention.

FIG. 12B shows the cross section of the integrated circuit die in another embodiment of the invention.

FIG. 12C shows the cross section of the integrated circuit die in another embodiment of the invention.

### DETAILED DESCRIPTION OF THE INVENTION

Some preferred embodiments of the conductive structure of the present invention on the surface of an integrated circuit die will be described in greater detail in the following. However, it should be recognized that the present invention can be practiced in a wide range of other embodiments besides the example of the embodiment. In an embodiment, the conductive structure is applied in an integrated circuit die. In another embodiment, the conductive structure is provided in various electronic devices, such as a printed circuit board (PCB).

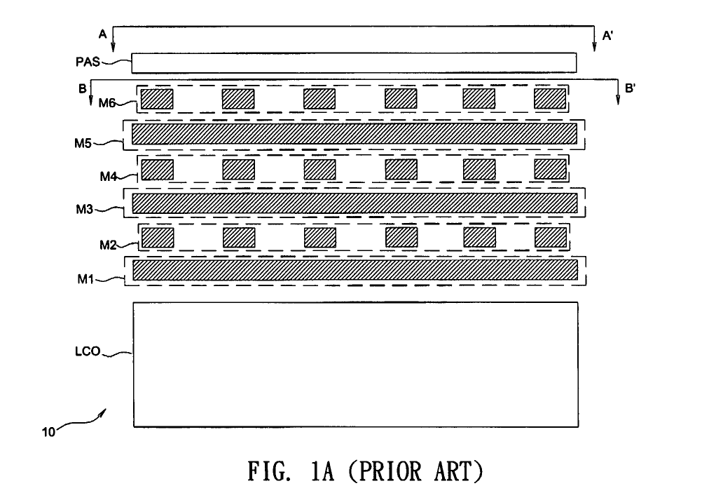

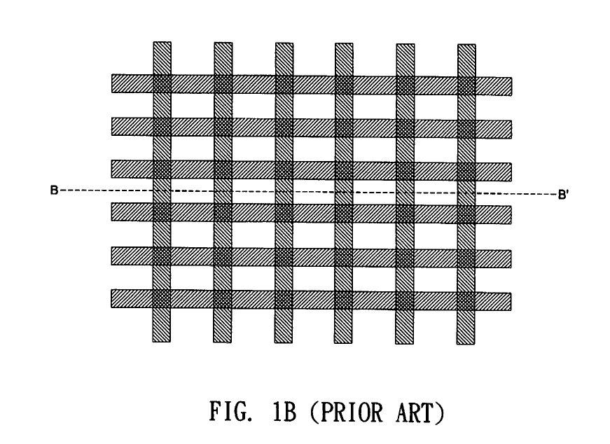

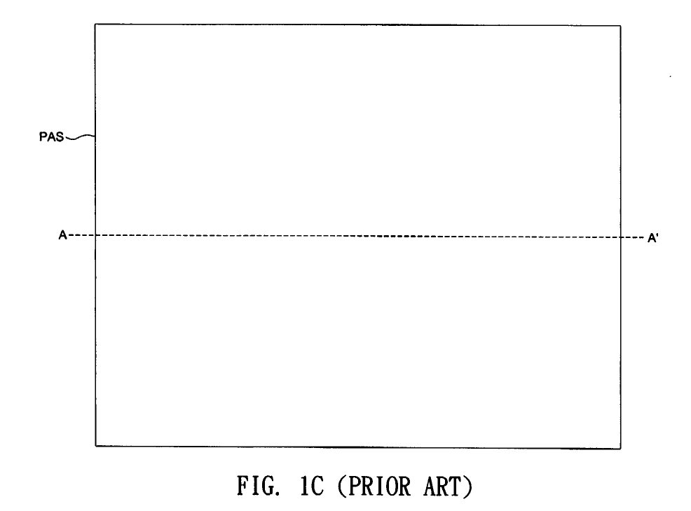

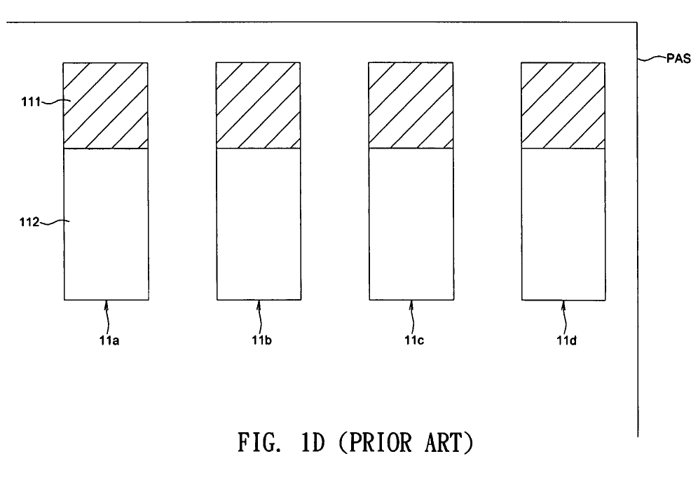

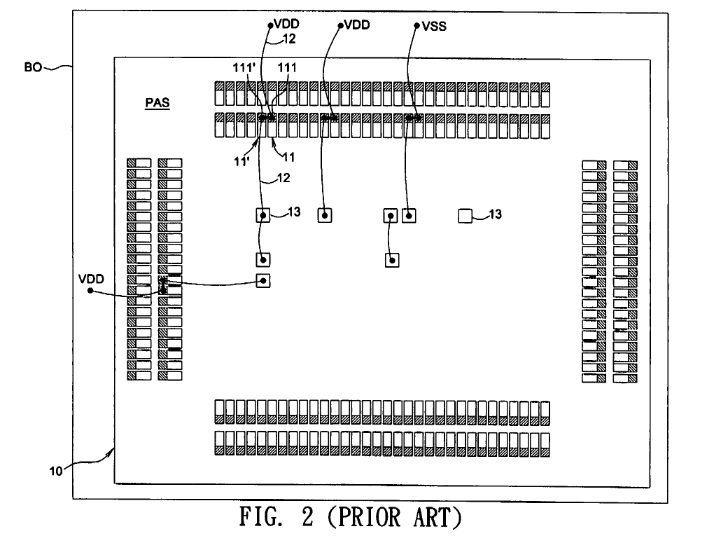

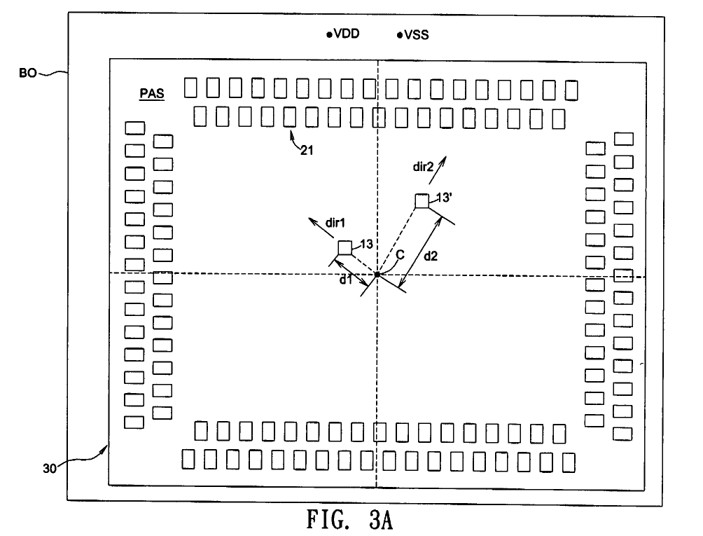

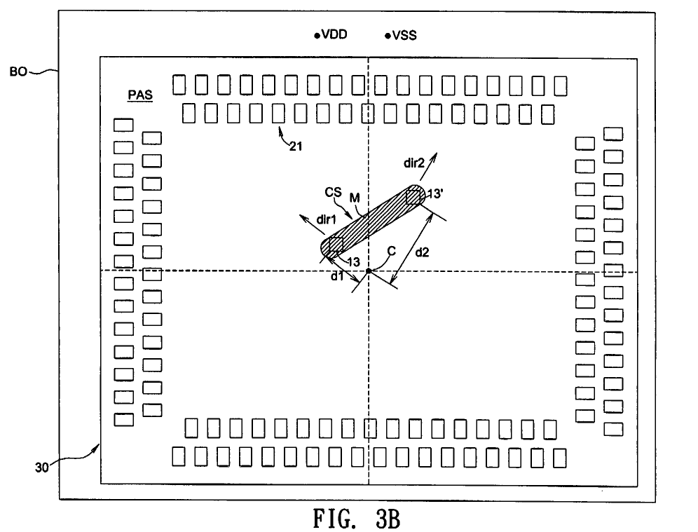

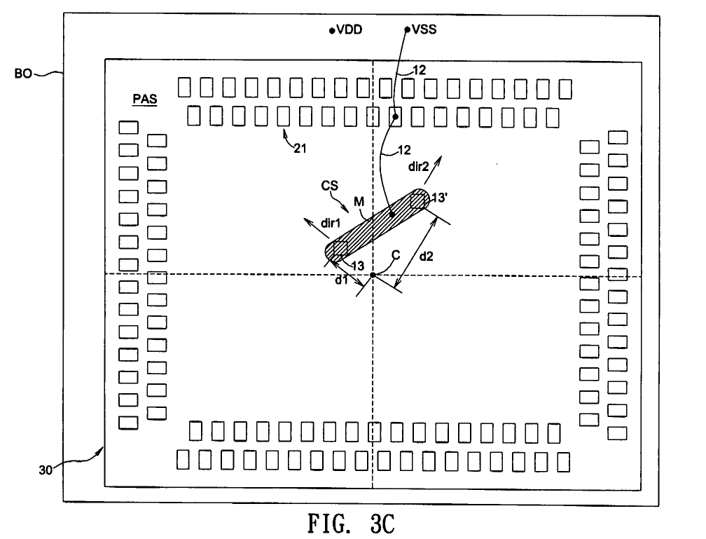

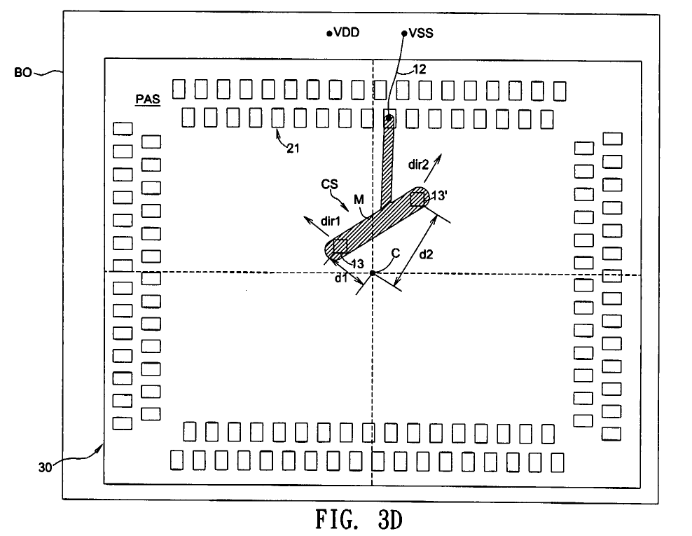

FIG. 3A is a schematic diagram illustrating a surface of an integrated circuit die 30 of the invention. Note that, in this embodiment, the top surface of the passivation layer PAS constitutes the surface of the integrated circuit die 30. In another embodiment of the invention, the integrated circuit die 30 may be formed without the formation of a passivation layer PAS and thus the top metal layer M6 in FIG. 1A constitutes the surface of the integrated circuit die 30. At least one electric power source VDD and at least one ground source VSS are provided at the outside of the integrated circuit die 30 (on the substrate BO). The electric power source VDD has high electric potential and the ground source VSS has ground potential or low electric potential. A plurality of input and output pads 21 and a plurality of internal bond pads 13 are formed on the top metal layer (said metal layer M6 in FIG. 1A) through the passivation openings of the passivation layer PAS of the IC die 30. However, since there are various types of input and output pads and the design of the invention is not limited to the input and output pads 11 illustrated in FIG. 1D and FIG. 2, the input and output pad with various different structures having similar function can be used in the invention. Therefore, the figure shows the common drawing of the input and output pads 21. Similarly, the method of allocating the bond pads on the surface of the IC die 30 is only an example and can be adjusted based on the circuit design requirements. In order to clearly describe the conductive structure CS of the invention, only two internal bond pads 13 and 13′ are shown in FIG. 3A and the center C of the IC die 30 is marked. The number of the internal bond pads 13 of the IC die 30 of the invention is not limited and is adjusted based on the requirements. As shown in the figure, the internal bond pad 13 is provided along a first direction dir1 and the internal bond pad 13′ is provided along a second direction dir2. The internal bond pads 13 and 13′ are provided at a first distance d1 and at a second distance d2 apart from the center C, respectively. The second distance d2 is greater than or equal to the first distance d1. The distance d1 can also be equal to zero while required. The azimuth angles of the first direction dir1 and the second direction dir2 can be any angle, such as any angle between 0 degree and 360 degrees. However, the azimuth angle of the first direction dir1 is not the same as that of the second direction dir2 in this embodiment. Of course, in another embodiment of the invention, the internal bond pad 13 may be also provided at the center C of the surface of the IC die 30.

FIG. 3B shows a schematic diagram illustrating the conductive structure CS of the invention. As shown in the figure, the conductive structure CS comprises internal bond pads 13 and 13′ and a conductive material M. The conductive material M is selected from the group consisting of sliver epoxy, solder paste, conductive film, passive component (such as zero ohm resistor), other conductive substance, and acombination of at least two of them. If connecting internal bond pads 13 and 13′ is required when designing the power distribution of the IC die 30, the designer can cover the internal bond pads 13 and 13′ with the conductive material M by using the silver epoxy dispensing machine used for die attach in the original process or using the substrate solder paste printing process on the passive component attaching process in the packaging assembly flow so as to connect the internal bond pads 13 and 13′. Note that a portion of the conductive material M touches the surface of the IC die 30. After the conductive material M is formed by the silver epoxy or solder paste dispensing process, the conductive material M is formed in a layer type and thus can be of any shape, such as rectangular, round, ring. Therefore, the conductive material M can be used as a bond joint. As shown in FIG. 3C, the designer can connect the conductive material M and the input and output pad 21 by using a bond wire 12, and connect the input and output pad 21 and the external electric power source VDD or ground source VSS by using another bond wire 12 to achieve the connection between the external electric power source VDD or ground source VSS and the conductive material M. In this embodiment, the prior bond wire 12 is attached on the conductive material M instead of being attached directly on the internal bond pads 13 and 13′, so that the application flexibility can be extended. Thus, the electric power source VDD or ground source VSS at the outside of the IC die 30 can be distributed to the two internal bond pad 13 and 13′ simultaneously and be leaded to a location near the center C of the IC die 30. Since the bond wire 12 is attached to the conductive material M that is not directly connected to the internal bond pads 13 and 13′, the internal circuit of the IC die 30 will not be damaged even when the force for attaching bond wire 12 is too strong so that the power distribution still can be achieved and the damage of the internal circuit of the IC die 30 can be avoided. On the other hand, as shown in FIG. 3D, the designer can also cover the connecting path from internal bond pads 13 and 13′ to the input and output pad 21 with the conductive material M so as to connect them at the same time by performing the silver epoxy or the solder paste dispensing process. The method for attaching the bond wire 12 to the conductive material M and the input and output pad 21 is cost effective and flexibility.

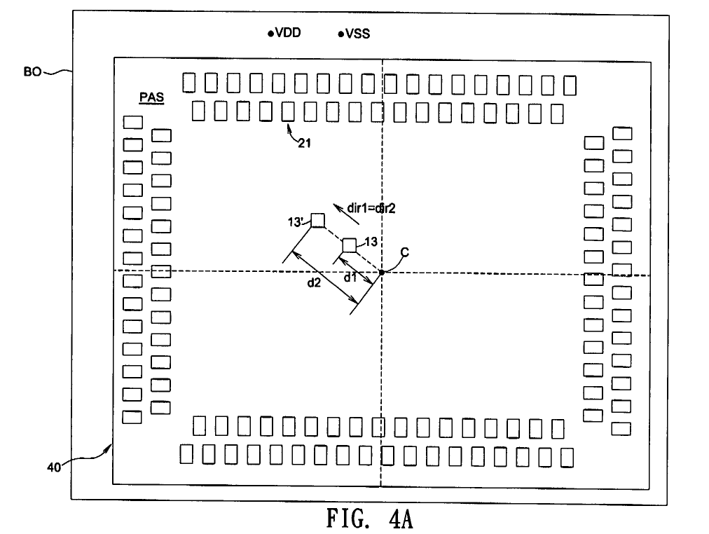

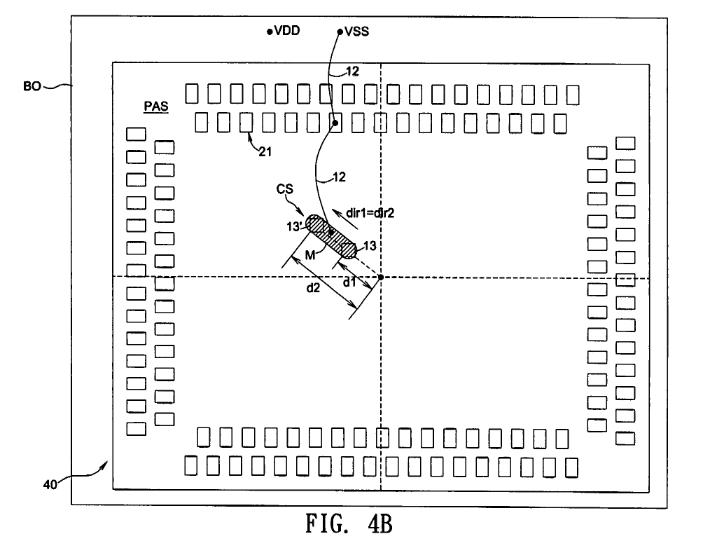

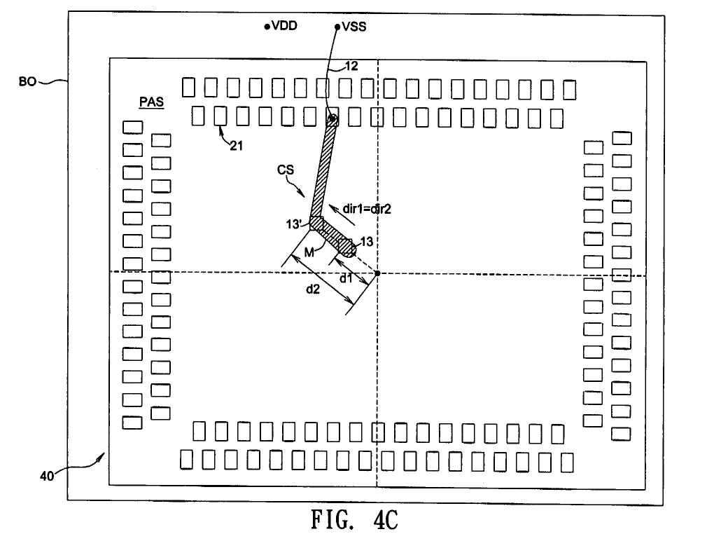

FIG. 4A shows a schematic diagram illustrating the surface of the passivation layer of the IC die 40 in another embodiment of the invention. The allocation structure of the bond pads on IC die 40 is similar to that of the IC die 30. The difference is that the internal bond pads 13 and 13′ are provided along the same direction dir1=dir2, that is the azimuth angle of the first direction dir1 is the same as that of the second direction dir2. Therefore, the first distance d2 between the center C and the internal bond pad 13′ must be set to be larger than the second distance d1 between the center C and the internal bond pad 13. Obviously, the azimuth angles of the directions dir1=dir2 can be of any angle, such as any angle between 0 degree and 360 degrees.

The technology shown in FIGS. 4B and 4C is the same as that in FIGS. 3C and 3D. When it is required to connect the internal bond pads 13 and 13′ for designing the power distribution of the IC die 40, the designer can use the silver epoxy or the solder paste dispensing process to connect the internal bond pads 13 and 13′ with the conductive material M or even to connect the input and output pad 21 at the same time so that the two internal bond pads 13 and 13′ or the three bond pads 13, 13′, and 21 are connected. As described, by the method of forming the conductive structure CS, the problem of damaging the internal circuits of the IC die 40 from traditional wire bond attaching process to connect the internal bond pads 13 and 13′ by the bond wire 12 can be avoided.

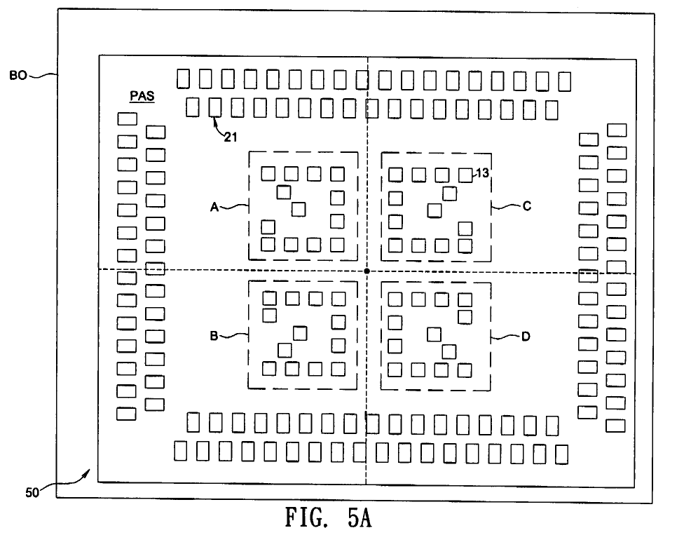

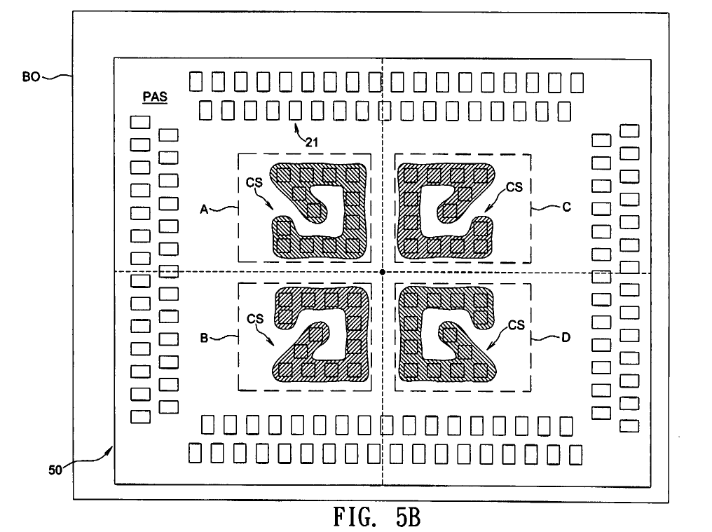

As shown in FIG. 5A, an IC die 50 includes a plurality of internal bond pads 13 and the internal bond pads 13 are provided in four areas A, B, C, and D according to the circuit design requirements. Each of the bond pads 13 within each area has to be connected with each other. In the conventional wire bond attaching method for attaching the bond wire 12 to the center area of the internal circuit structure of the IC die 50, the internal circuit structure will be damaged during the wire bond attaching process. However, by applying the conductive structure CS of the invention, each of the internal bond pads 13 within each of the areas A, B, C, and D can be connected without increasing the process step and cost, and it is safe from damaging the internal circuit structure of the IC die 50, as shown in FIG. 5B.

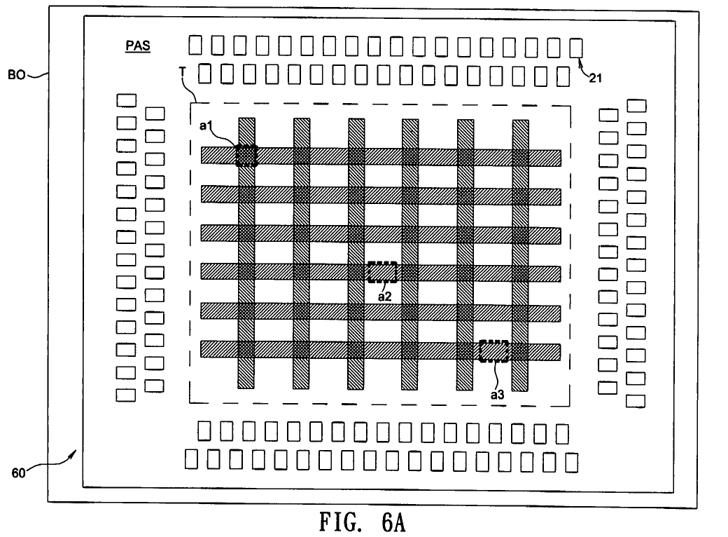

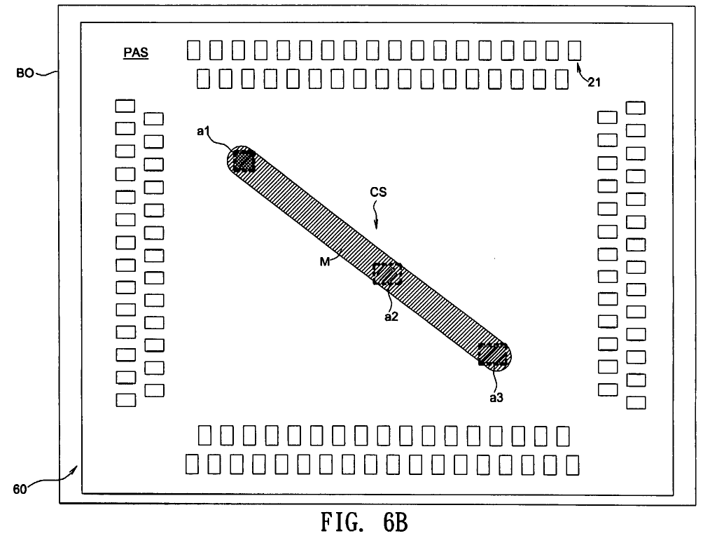

Furthermore, according to the design concept of the conductive structure CS of the invention to design the power distribution, the conductive structure CS is formed by connecting a metal wire and a conductive material M without providing any internal bond pad 13 on the top metal layer but only open the passivation layer PAS to form a passivation opening on the desired connecting area of the connecting metal wire on the top metal layer M6 of the IC die. As shown in FIG. 6A, by visualizing through the dotted line block T of the passivation layer PAS of the IC die 60, the metal layer is shown in a mesh-like structure. The designer can introduce the electric power source VDD or ground source VSS into the areas a1, a2, and a3 by removing the passivation layer PAS over the areas a1, a2, and a3 and then covering the areas a1, a2, and a3 with the conductive material M in the silver epoxy or solder paste dispensing process, as shown in FIG. 6B. Thus, the electric power or ground can be evenly distributed among the areas a1, a2, and a3 and the electric power source VDD or ground source VSS can be introduced to the center of the IC die 60.

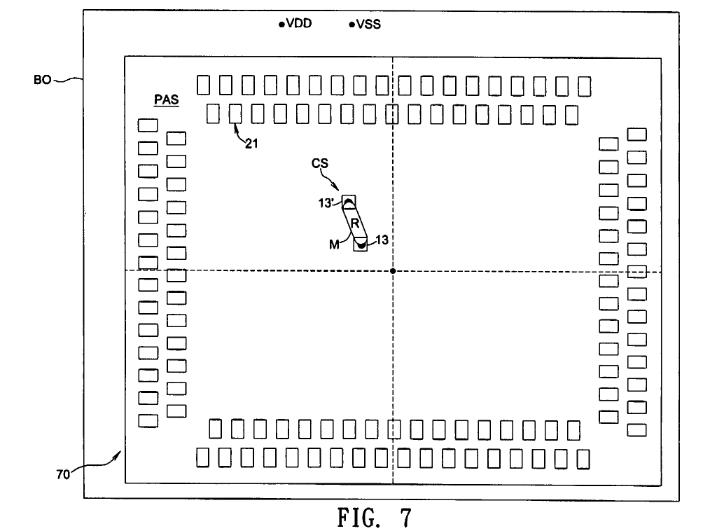

FIG. 7 shows a schematic diagram illustrating a passive component (a zero ohm resistor R) which is used as the conductive material M to connect the two internal bond pads 13 and 13′. The zero ohm resistor R connects the internal bond pads 13 and 13′ through the solder paste printing process which is commonly used on the passive component mounting of the packaging substrate so as to form the conductive structure CS of the invention.

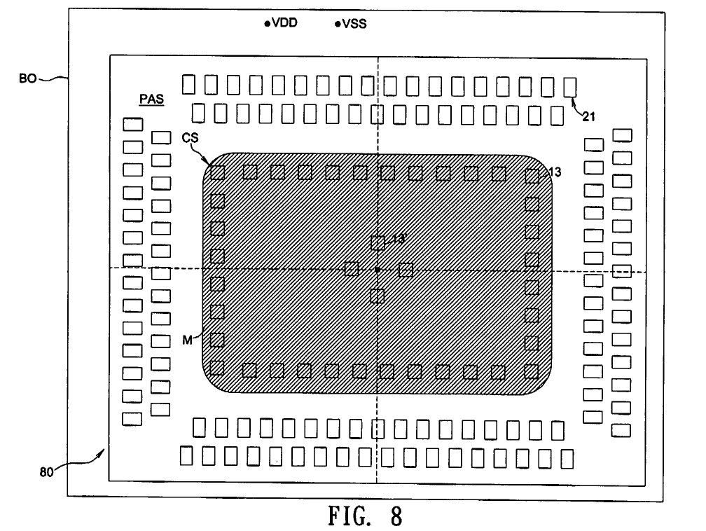

FIG. 8 shows a schematic diagram illustrating the internal bond pad arrangement on an IC die 80 of the invention. As shown in the figure, a plurality of internal bond pads 13 are provided at the locations farther away from the center C and roughly in a rectangular shape while four internal bond pads 13′ are provided nearer the center C. When designing the power and ground distribution, the exterior internal bond pads 13 are connected to the electric power source VDD or ground source VSS. By the silver epoxy or soldering paste material dispensing process, each of the internal bond pads 13 and 13′ is covered with the conductive material M so as to form the conductive structure CS. Finally, the electric power source VDD or ground source VSS is introduced to each of the internal bond pads 13 and 13′. Since the area of the conductive structure CS is relatively larger in dimension with the metal trace inside the IC die and the electrical resistance of silver epoxy or solder paste is small, it is easy to form a low electrical resistance passage from the edge to the center area of the IC die 80. The problem of the uneven IR drop of the electric power and ground distributing between the edge and the center of the IC die 80 is solved. Since the area of the conductive structure CS is large, the heat dissipating area is also increased. With this invention, not only does the IC die 80 dissipate heat more quickly, but also is the problem of hot spot in the IC die 80 effectively solved.

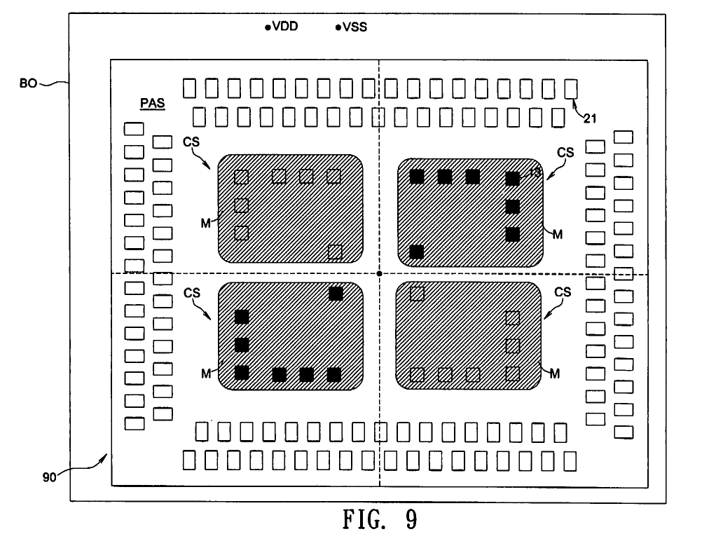

FIG. 9 shows a schematic diagram illustrating bond pads allocation of an IC die 90 of the invention. A plurality of internal bond pads 13 are provided in four areas. In order to distinguish internal bond pads 13 for being connected with either the electric power source VDD or the electric ground source VSS, the internal bond pad 13 marked black is used to be connected with the electric power source VDD while the internal bond pad 13 not marked in black is used to be connected with the electric ground source VSS. By the silver epoxy or soldering paste material dispensing process, each of the internal bond pads 13 in each area is covered with the conductive material M to form the four sets of the conductive structures CS. Of course, since the area of the conductive structure CS is relatively larger in dimension with the metal trace inside the IC die and the electrical resistance of silver epoxy or solder paste is small, it is easy to form a low electrical resistance passage from the edge to the center area of the IC die 90. By doing so, not only the problem of uneven IR drop of the electric power distributing is solved but also does the IC die 90 dissipate heat more quickly so as to solve the problem of hot spot in the IC die 90.

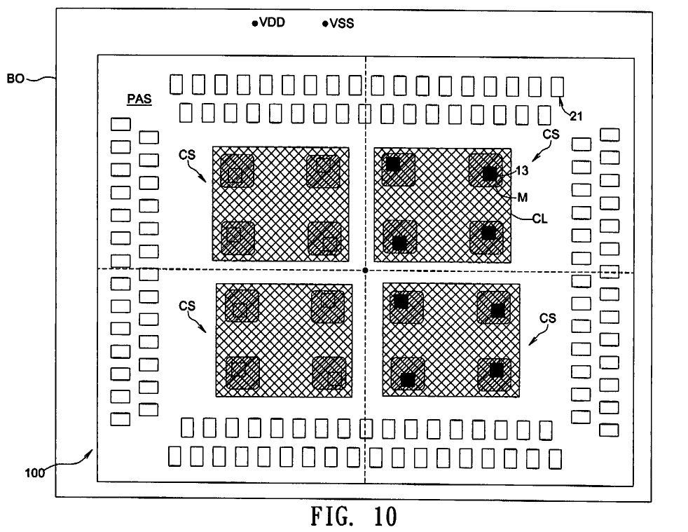

FIG. 10 shows a schematic diagram illustrating the bond pads allocation of an IC die 100 of the invention. A plurality of internal bond pads 13 are provided in four areas. The internal bond pad 13 marked black is used to be connected with the electric power source VDD while the internal bond pad 13 not marked in black is used to be connected with the electric power source VSS. By the silver epoxy or soldering paste material dispensing process, each of the internal bond pads 13 in each area is covered with the conductive material M. A secondly conductive substance CL is formed above the conductive material M and cover the area formed by the conductive structures CS to form four sets of conductive areas in this embodiment. The secondly conductive substance CL can be a thin film plated on the conductive material M. Obviously, the secondly conductive substance CL can also be a conductive metal plate that is securely fixed on the conductive material M. Or, the secondly conductive substance CL can also be a conductive material on the surface of another IC die with conductive area on the surface. Thus, the another IC die can be flipped to let the conductive surface of the another IC die directly contact the conductive material M to form the conductive structure CS. The conductive substance CL on the surface of another IC die can be selected from the group consisting of aluminum layer, copper or other conductive materials. Since the area of the conductive structure CS is wide range in such a design, not only is the problem of the uneven IR drop of the electric power or ground distributing solved but also does the IC die 100 dissipate heat more quickly to effectively solve the problem of hot spot.

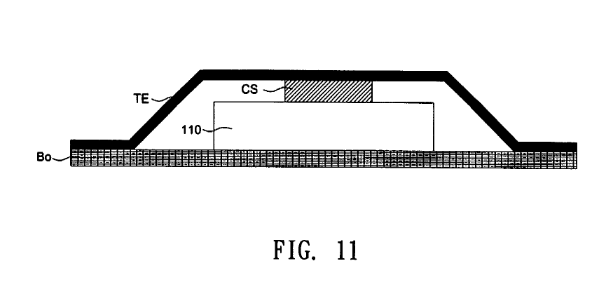

FIG. 11 shows a cross section illustrating the finished product of an IC die 110 after the electronic assembly. At least one conductive structure CS is formed on the surface of the IC die 110 after processing according to the conductive structure of the invention. According to the design, the electric power source VDD or ground source VSS on the substrate BO can be connected directly by connecting the conductive material M, bond pad, metal wire, or plated conductive substance CL of the conductive structure CS to the heat sink (TEBGA) TE during the packaging process. By such an approach, the electric power at the outside of the IC die 10 can be connected directly near the center of the IC die 110 to achieve the proper electric power or ground distribution at lower cost. By connecting any of the components of the conductive structure CS to a heat sink, the heat generated during the operation of the IC die 110 can be dissipated through the conduction between the conductive structure CS and the heat sink TE.

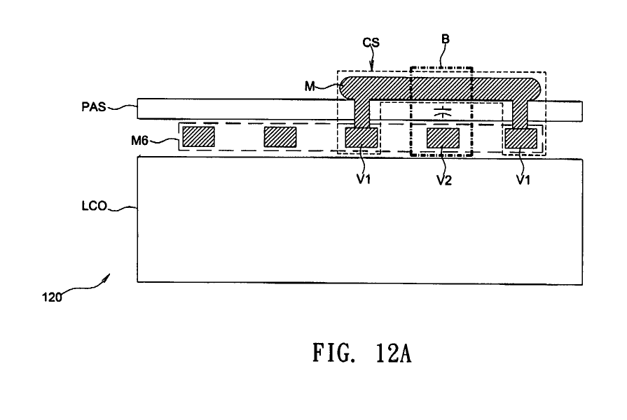

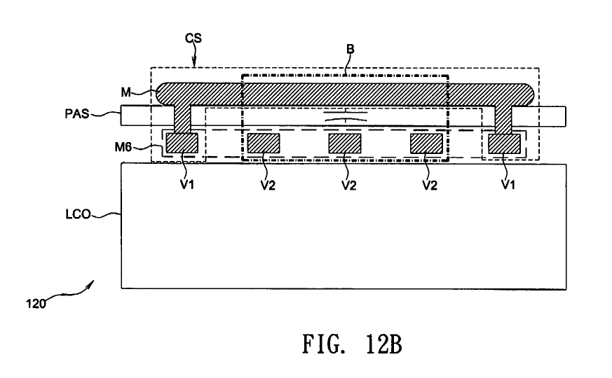

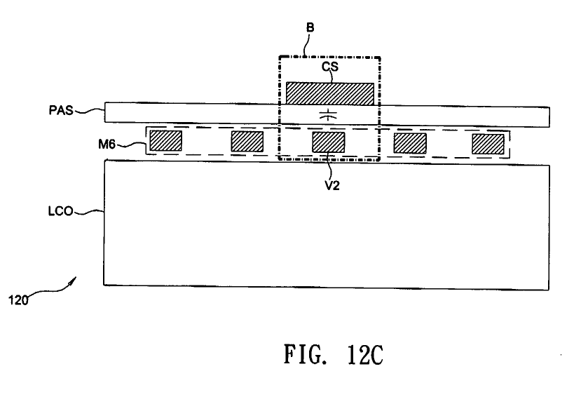

FIG. 12A further illustrates that all of the internal bond pads can be constructed to a single electrical net on metal wire layer M6 through the connection of using the conductive structure CS of the invention. An IC die 120 can also be designed so that the conductive material M is connected to a metal wire V1 of the metal wire layer M1 and is not connected to another metal wire V2 with different electrical net. When the electric potential of the metal wire V1 is different from that of the metal wire V2, such as being electric power or ground, respectively, a structure that functions as a decouple capacitor is formed because the passivation layer PAS exists between the conductive material M and the metal wire V2 to form the dielectric layer, as shown by the area B so as to provide an additional functionality for the invention. As shown in FIG. 12B, when the conductive material M is connected to the two ends of the metal wire V1 and is not connected the other three metal wires V2 with different electric net, a decouple capacitor with larger capacitance is formed by the conductive material M, the passivation layer PAS, and the three metal wires V2. Furthermore, as shown in FIG. 12C, a decouple capacitor structure can also be formed by the conductive structure CS already formed, the passivation layer PAS, and the metal wire V2 with different electric net.

Since the conductive structure CS of the invention can be formed on every IC die, if metal is formed on the IC die then the IC die can be conducted by the conductive structure CS to provide the functionality of the prevention of the electrostatic discharge (ESD) or the electromagnetic Interfere (EMI).

While the invention has been described by way of examples and in terms of the preferred embodiments, it is to be understood that the invention is not limited to the disclosed embodiments. To the contrary, it is intended to cover various modifications and similar arrangements as would be apparent to those who are skilled in the art. Therefore, the scope of the appended claims should be accorded the broadest interpretation so as to encompass all such modifications and similar arrangements.

What is claimed is:

1. A conductive structure for an electronic device, comprising:
at least a first conductor on the electronic device connected to an internal circuitry of the electronic device and provided at a first location on a surface of the electronic device, wherein the first location is apart from the center of the electronic device by a first distance in a first direction;
at least a second conductor on the electronic device connected to an internal circuitry of the electronic device and provided at a second location on the surface of the electronic device, wherein the second location is apart from the center of the electronic device by a second distance in a second direction and the second distance is larger than or equal to the first distance; and
a conductive material connecting the first conductor and the second conductor, wherein a portion of the conductive material touches the surface of the electronic device.

2. The conductive structure for an electronic device according to claim 1, wherein the conductive material, the first conductor, and the second conductor are connected by a process of dispensing a silver epoxy or a solder paste.

3. The conductive structure for an electronic device according to claim 1, wherein at least one electric power source and at least one ground source are provided outside the electronic device and the conductive structure is connected to the at least one electric power source or the at least one ground source by a bond wire or a heat sink.

4. The conductive structure for an electronic device according to claim 1, wherein the conductive material is selected from the group consisting of sliver epoxy, solder paste, conductive film, passive component, and a combination of at least two of them.

5. The conductive structure for an electronic device according to claim 1, wherein the conductive material is formed as a bond joint for attaching a bond wire and the bond joint connects to an input and output pad by the bond wire.

6. The conductive structure for an electronic device according to claim 1, wherein the first conductor is an internal bond pad, an input and output pad, an aluminum layer or a metal wire in the electronic device.

7. The conductive structure for an electronic device according to claim 6, wherein the second conductor is an internal bond pad, an input and output pad, an aluminum layer or a metal wire in the electronic device.

8. The conductive structure for an electronic device according to claim 1, wherein the electronic device is an integrated circuit die.

9. The conductive structure for an electronic device according to claim 1, wherein the second distance is larger than the first distance when the azimuth angle of the first direction is equal to that of the second direction.

10. The conductive structure for an electronic device according to claim 1, wherein the second distance is larger than or equal to the first distance when the azimuth angle of the first direction is not equal to that of the second direction.

11. A conductive structure for an integrated circuit die[u1], comprising:
at least a first conductor connected to an internal circuitry of the integrated circuit die and provided at a first location on a surface of the integrated circuit die wherein the first location is apart from the center of the surface by a first distance in a first direction;
at least a second conductor on an internal circuitry of the integrated circuit die and provided at a second location on the surface of the integrated circuit die wherein the second location is apart from the center of the integrated circuit die by a second distance in a second direction from the center of the integrated circuit die and the second distance is larger than or equal to the first distance; and
a conductive material outside the integrated circuit die for connecting the first conductor and the second conductor, wherein a portion of the conductive material touches the surface of the integrated circuit die.

12. The conductive structure for an integrated circuit die according to claim 11, wherein the conductive material, the first conductor, and the second conductor are connected by a process of dispensing a silver epoxy or a solder paste.

13. The conductive structure for an integrated circuit die according to claim 11, wherein at least one electric power source and at least one ground source are provided at the outside of the integrated circuit die and the conductive structure is connected to the at least one electric power source or the at least one ground source by a bond wire or a heat sink.

14. The conductive structure for an integrated circuit die according to claim 11, wherein the conductive material is selected from the group consisting of sliver epoxy, solder paste, conductive film, passive component, and a combination of at least two of them.

15. The conductive structure for an integrated circuit die according to claim 11, wherein the conductive material is formed as a bond joint for attaching a bond wire and the bond joint connects to an input and output pad by the bond wire.

16. The conductive structure for an integrated circuit die according to claim 11, wherein the first conductor is an internal bond pad, an input and output pad, an aluminum layer or a metal wire in the integrated circuit die.

17. The conductive structure for an integrated circuit die according to claim 16, wherein the second conductor is an internal bond pad, an input and output pad, an aluminum layer or a metal wire in the integrated circuit die.

18. The conductive structure for an integrated circuit die according to claim 11, wherein the second distance is larger than the first distance when the azimuth angle of the first direction is equal to that of the second direction.

19. The conductive structure for integrated circuit die according to claim 11, wherein the second distance is larger than or equal to the first distance when the azimuth angle of the first direction is not equal to that of the second direction.

20. A conductive structure for an electronic device, comprising:
at least a first conductor on the electronic device connected to an internal circuitry of the electronic device and provided at the center of a surface of the electronic device;
at least a second conductor on the electronic device connected to an internal circuitry of the electronic device and provided at a location on the surface of the electronic device wherein the location is apart from the center of the electronic device by a distance in a direction; and
a conductive material connecting the first conductor and the second conductor, wherein a portion of the conductive material touches the surface of the electronic device.

21. The conductive structure for an electronic device according to claim 20, wherein the conductive material, the first conductor, and the second conductor are connected by a process of dispensing a silver epoxy.

22. The conductive structure for an electronic device according to claim 20, wherein the conductive material, the first conductor, and the second conductor are connected by a process of dispensing a solder paste.

23. The conductive structure for an electronic device according to claim 20, wherein at least one electric power source and at least one ground source are provided outside the electronic device.

24. The conductive structure for an electronic device according to claim 20, wherein the conductive structure is connected to at least one electric power source or at least one ground source by a bond wire or a heat sink.

25. The conductive structure for an electronic device according to claim 20, wherein the conductive material is selected from the group consisting of sliver epoxy, solder paste, conductive film, passive component, and a combination of at least two of them.

26. The conductive structure for an electronic device according to claim 20, wherein the conductive material is formed as a bond joint for attaching a bond wire and the bond joint connects to an input and output pad by the bond wire.

27. The conductive structure for an electronic device according to claim 20, wherein the first conductor is an internal bond pad, an input and output pad, an aluminum layer or a metal wire in the electronic device.

28. The conductive structure for an electronic device according to claim 27, wherein the second conductor is an internal bond pad, an input and output pad, an aluminum layer or a metal wire in the electronic device.

29. The conductive structure for an electronic device according to claim 20, wherein the electronic device is an integrated circuit die.
